(19) United States
(12) Patent Application Publication
(10) Pub. No.: US 2009/0211793 A1
(43) Pub. Date: Aug. 27, 2009

(54) SUBSTRATE MODULE, METHOD FOR MANUFACTURING SUBSTRATE MODULE, AND ELECTRONIC DEVICE

(76) Inventors: Takahiro NAKANO, Kyoto (JP); Masanori Minamio, Osaka (JP); Yoshihiro Tomita, Osaka (JP); Hikari Sano, Hyogo (JP)

Correspondence Address: MCDERMOTT WILL & EMERY LLP, 600 13TH STREET, NW, WASHINGTON, DC, 20005-3096, US

(21) Appl. No.: 12/330,923

(22) Filed: Dec. 9, 2008

(30) Foreign Application Priority Data
Feb. 21, 2008 (JP) 2008-039995

(51) Int. Cl. H05K 1/18; H05K 3/02

(52) U.S. Cl. 174/260; 29/846; 174/262

(57) ABSTRACT

In a substrate module of the present invention, a connection electrode is provided on a first surface of a substrate, and a first penetrating hole portion is running through the substrate in a thickness direction thereof so as to reach a reverse surface of the connection electrode, with a penetrating electrode being provided inside the first penetrating hole portion. The penetrating electrode defines a depression in a position opposing the reverse surface of the connection electrode, and an upper portion of the penetrating electrode is thicker than a side portion of the penetrating electrode. The penetrating electrode is present also on a second surface of the substrate, and is connected to a wiring electrode on the second surface.

### BACKGROUND OF THE INVENTION

1. Field of the Invention

The present invention relates to a substrate module, a method for manufacturing a substrate module, and an electronic device including a substrate module.

2. Description of the Background Art

Recent electronic devices often use a substrate module including various electronic components integrated therein in order to thereby increase the productivity of the electronic devices or reduce the overall size, the thickness and the weight thereof. A substrate module including electronic components integrated therein typically has a configuration as follows.

For example, a conventional substrate module includes a substrate, an electronic component, a connection electrode, a first penetrating hole portion, a penetrating electrode, a wiring electrode, and a mounting electrode. The electronic component is provided on the first surface of the substrate or inside the substrate. The connection electrode is provided on the first surface of the substrate while being electrically connected to the electronic component. The first penetrating hole portion runs through the substrate from the second surface to the first surface to reach the reverse surface of the connection electrode. The penetrating electrode is provided inside the first penetrating hole portion, and extends from inside the first penetrating hole portion toward the second surface of the substrate. The wiring electrode is electrically connected to the penetrating electrode on the second surface of the substrate, and the mounting electrode is electrically connected to the wiring electrode (such a substrate module is disclosed in, for example, Japanese Laid-Open Patent Publication No. 2007-73958).

Another conventional substrate module includes a connection electrode, a first penetrating hole portion, a penetrating electrode, a wiring electrode, and a mounting electrode. The connection electrode is provided on the first surface of the substrate, and the first penetrating hole portion runs not only through the substrate but also through the connection electrode. The penetrating electrode is provided inside the first penetrating hole portion, and extends from inside the first penetrating hole portion toward the second surface of the substrate. The wiring electrode is electrically connected to the penetrating electrode on the second surface of the substrate, and the mounting electrode is electrically connected to the wiring electrode (such a substrate module is disclosed in, for example, Japanese Laid-Open Patent Publication No. 2007-134735).

### SUMMARY OF THE INVENTION

In a conventional module as described above, where the penetrating electrode has a uniform thickness entirely across the inner surface of the penetrating hole (i.e., where the penetrating electrode has the same thickness on the reverse surface of the connection electrode and on the side surface of the first penetrating hole portion), if the first surface of the substrate receives a stress urging the connection electrode to peel off, the connection electrode may be disconnected or peeled off together with the penetrating electrode.

It is an object of the present invention to prevent disconnection and peeling of the connection electrode.

A substrate module of the present invention includes: a substrate; an electronic component provided on a first surface of the substrate or inside the substrate; a connection electrode provided on the first surface of the substrate while being connected to the electronic component; a first penetrating hole portion running through the substrate in a thickness direction thereof so as to reach a reverse surface of the connection electrode; a penetrating electrode provided inside the first penetrating hole portion so as to extend from inside the first penetrating hole portion to a second surface of the substrate; and a wiring electrode provided on the second surface of the substrate and connected to the penetrating electrode on the second surface of the substrate. Inside the first penetrating hole portion, the penetrating electrode defines a depression in a position opposing the reverse surface of the connection electrode, and a thickness of the penetrating electrode on the reverse surface of the connection electrode is greater than that on a side surface of the first penetrating hole portion.

In a substrate module as set forth above, the upper portion of the penetrating electrode is thicker than the side portion thereof, whereby it is possible to increase the adhesion strength between the connection electrode and the penetrating electrode on the first surface of the substrate. As a result, it is possible to suppress the peeling of the connection electrode off the first surface of the substrate.

Specifically, when there is a stress urging the connection electrode to peel off the first surface of the substrate, and if the thickness of the penetrating electrode connected to the reverse surface of the connection electrode is small, the connection electrode may be disconnected and peeled off, by being ripped off, together with the upper portion of the penetrating electrode, by the external peeling stress. However, since the upper portion of the penetrating electrode is thicker than the side portion thereof in the present invention, the connection electrode is unlikely to be ripped off together with the upper portion of the penetrating electrode. Thus, it is possible to suppress the peeling of the connection electrode off the first surface of the substrate.

It is preferred that the thickness of the penetrating electrode on the reverse surface of the connection electrode is greater than a thickness of the wiring electrode. It is preferred that the thickness of the penetrating electrode on the reverse surface of the connection electrode is greater than a thickness of the connection electrode.

It is preferred that the substrate module further includes an insulating layer provided on the second surface of the substrate so as to cover a surface of the wiring electrode, wherein the insulating layer is present also in the depression of the penetrating electrode.

In a substrate module as set forth above, the penetrating electrode defines a depression in a position opposing the reverse surface of the connection electrode, the penetrating electrode is thicker on the reverse surface of the connection electrode than on the side surface of the first penetrating hole portion, and the insulating layer is provided in the depression of the penetrating electrode. Therefore, the insulating layer is unlikely to peel off. The term “an upper portion of the penetrating electrode” as used herein refers to a portion of the penetrating electrode that is provided on the reverse surface of the connection electrode, and the term “a side portion of the penetrating electrode” as used herein refers to a portion of the penetrating electrode that is provided on the side surface of the first penetrating hole portion.

Thus, the depression of the penetrating electrode is filled by a portion of the insulating layer, and this portion of the insulating layer in the depression serves as a “root” so to speak, and also the contact area between the insulating layer and the penetrating electrode increases. As a result, the insulating layer is unlikely to peel off due to a thermal stress, an external stress, or the like. Thus, it is possible to ensure the electrical insulation between the wiring electrodes and to protect the wiring electrodes (it is possible to prevent peeling, disconnection, discoloration, corruption, etc., of the wiring electrodes).

Moreover, the penetrating electrode defines a depression in a position opposing the reverse surface of the connection electrode, the upper portion of the penetrating electrode is thicker than the side portion thereof, and the depression of the penetrating electrode is filled by the insulating layer, whereby it is possible to further suppress the peeling of the connection electrode off the first surface of the substrate.

Specifically, as the portion of the insulating layer in the depression of the penetrating electrode cures, there is a contractile force acting upon the insulating layer. Then, if the upper portion of the penetrating electrode is thinner than the side portion thereof, the contractile force of the insulating layer is transmitted to the connection electrode through the upper portion of the penetrating electrode. As a result, the connection electrode may be disconnected or peeled off together with the upper portion of the penetrating electrode in the direction from the first surface of the substrate toward the second surface of the substrate. In contrast, since the upper portion of the penetrating electrode is thicker than the side portion thereof in the present invention, the contractile force of the insulating layer is unlikely to be transmitted to the connection electrode through the upper portion of the penetrating electrode. As a result, it is possible to suppress disconnection or peeling of the connection electrode together with the upper portion of the penetrating electrode.

In a substrate module including an insulating layer as set forth above, it is preferred that: a second penetrating hole is formed in the insulating layer; a mounting electrode is provided in the second penetrating hole; and the mounting electrode is connected to the wiring electrode. The insulating layer may be made of a thermosetting resin or a UV curable resin.

In the substrate module of the present invention, it is preferred that the penetrating electrode is made of copper or a metal whose main component is copper.

In the substrate module of the present invention, it is preferred that the substrate is made of silicon; a thin silicon oxide film, a thin titanium-based metal film or a thin chromium film, and a thin copper film are formed in this order on the side surface of the first penetrating hole portion; and the penetrating electrode is made of a metal whose main component is copper and is provided on a surface of the thin copper film. It is preferred that the thin silicon oxide film is absent between the penetrating electrode and the connection electrode.

It is preferred that a diameter of the first penetrating hole portion on the first surface of the substrate is smaller than that on the second surface of the substrate, and the first penetrating hole portion is tapered.

A method for manufacturing a substrate module of the present invention includes: a step (a) of providing a connection electrode connected to the electronic component on a first surface of a substrate; a step (b) of forming a first penetrating hole portion running through the substrate in a thickness direction thereof so as to reach a reverse surface of the connection electrode; a step (c) of providing a penetrating electrode inside the first penetrating hole portion so that the penetrating electrode extends from inside the first penetrating hole portion to a second surface of the substrate; and a step (d) of providing a wiring electrode on the second surface of the substrate, and connecting together the wiring electrode and the penetrating electrode on the second surface of the substrate. In the step (c), the penetrating electrode is provided so that a thickness of the penetrating electrode on the reverse surface of the connection electrode is greater than that on a side surface of the first penetrating hole portion, with the penetrating electrode defining a depression in a position opposing the reverse surface of the connection electrode.

It is preferred that the method for manufacturing a substrate module of the present invention further includes a step (e) of providing an insulating layer on the second surface of the substrate so as to cover a surface of the wiring electrode, wherein in the step (e), the insulating layer is inserted into the depression of the penetrating electrode. It is preferred that the method for manufacturing a substrate module of the present invention further includes: a step (f) of forming a second penetrating hole in the insulating layer; and a step (g) of providing a mounting electrode inside the second penetrating hole, and connecting together the mounting electrode and the wiring electrode.

In the method for manufacturing a substrate module of the present invention, it is preferred that the step (c) and the step (d) are performed simultaneously.

An electronic device of the present invention includes: the substrate module as set forth above; and a wiring substrate, wherein the mounting electrode of the substrate module is provided on a surface of the wiring substrate and is connected to the wiring substrate.

### BRIEF DESCRIPTION OF THE DRAWINGS

FIG. 1 is a cross-sectional view showing a substrate module 1 according to an embodiment of the present invention.

FIG. 2 is an enlarged cross-sectional view showing an important part of the substrate module 1.

### DETAILED DESCRIPTION OF THE PREFERRED EMBODIMENTS

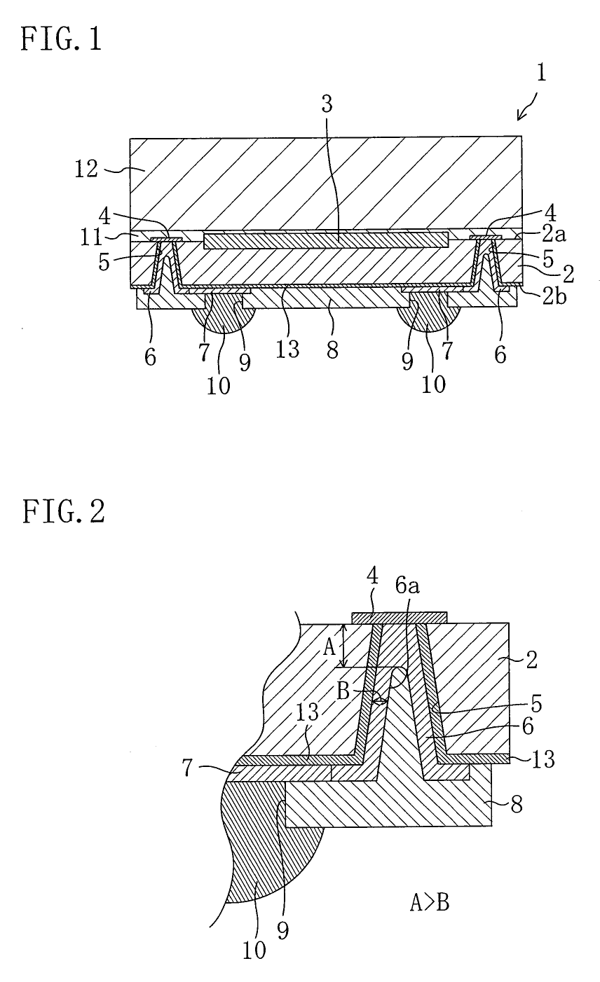

An embodiment of the present invention will now be described with reference to FIGS. 1 and 2.

FIG. 1 is a cross-sectional view showing a substrate module 1 to be mounted on a main substrate (not shown) of an electronic device such as a digital still camera, for example. The substrate module 1 includes a substrate 2, an electronic component 3, a connection electrode 4, a first penetrating hole portion 5, a penetrating electrode 6, a wiring electrode 7, an insulating layer 8, a mounting electrode 10, and a glass plate 12. The electronic component 3 is provided on a first surface (upper surface) 2a of the substrate 2 or inside the substrate 2. The connection electrode 4 is provided on the first surface 2a of the substrate 2 while being electrically connected to the electronic component 3, and the main component of the connection electrode 4 is a metal such as aluminum or copper. The first penetrating hole portion 5 extends from the reverse surface of the connection electrode 4 toward a second surface (lower surface) 2b of the substrate 2, and runs completely through the substrate 2 in the thickness direction thereof. The penetrating electrode 6 is provided inside the first penetrating hole portion 5, and extends from inside the first penetrating hole portion 5 to the second surface 2b of the substrate 2. The wiring electrode 7 is provided on the second surface 2b of the substrate 2 and is electrically connected to the penetrating electrode 6 thereon. The insulating layer 8 is provided on the second surface 2b of the substrate 2 so as to cover the surface of the wiring electrode 7. The mounting electrode 10 is provided in a second penetrating hole 9 formed in a portion of the insulating layer 8, and is electrically connected to the wiring electrode 7. The glass plate 12 is attached to the first surface 2a of the substrate 2 via an adhesive 11.

Thus, the electronic component 3 (e.g., an image-sensing device) on the first surface 2a of the substrate 2 is electrically connected to the mounting electrode 10 on the second surface 2b of the substrate 2 via the connection electrode 4, the penetrating electrode 6 and the wiring electrode 7. Therefore, image information and image data are received by the electronic component 3 via the glass plate 12, and then transmitted to the main substrate (not shown) of the electronic device (e.g., a digital still camera) via the connection electrode 4, the penetrating electrode 6, the wiring electrode 7 and the mounting electrode 10. Although not shown in FIGS. 1 and 2, a plurality of connection electrodes 4, 4, . . . , are provided at predetermined intervals therebetween on the first surface 2a of the substrate 2 around the electronic component 3 (e.g., an image-sensing device), and a plurality of penetrating electrodes 6, 6, . . . , a plurality of wiring electrodes 7, 7, . . . , and a plurality of mounting electrodes 10, 10, . . . , are provided on the second surface 2b of the substrate 2, wherein one connection electrode 4 is electrically connected to a corresponding mounting electrode 10 via the penetrating electrode 6 and the wiring electrode 7, which are connected to the connection electrode 4.

The penetrating electrode 6 is plated with copper or a metal whose main component is copper (the manufacturing method will be described later), and includes a depression 6a in a position opposing the reverse surface of the connection electrode 4. The thickness (“A” in FIG. 2) of an upper portion of the penetrating electrode 6 is larger than the thickness (“B” in FIG. 2) of a side portion of the penetrating electrode 6. While the second surface 2b of the substrate 2 is covered with the insulating layer 8 made of a resin (e.g., a thermosetting resin or a UV curable resin) for the protection of the wiring electrodes 7 and the electrical insulation therebetween, a portion of the insulating layer 8 is inserted into the depression 6a of the penetrating electrode 6 from the second surface 2b of the substrate 2, as shown in FIG. 2. With such a structure, the insulating layer 8 is unlikely to peel off.

Specifically, as a portion of the insulating layer 8 is inserted into the depression 6a of the penetrating electrode 6 from the side of the second surface 2b of the substrate 2, the inserted portion (a portion of the insulating layer 8 that is present in the depression 6a) serves as a “root” so to speak, and also the contact area between the insulating layer 8 and the penetrating electrode 6 increases. As a result, the insulating layer 8 is unlikely to peel off due to a thermal stress, an external stress, or the like, and it is possible to ensure the electrical insulation between the wiring electrodes 7 and to protect the wiring electrodes 7 (it is possible to prevent peeling, disconnection, discoloration, corruption, etc., of the wiring electrodes 7).

Moreover, with the thickness (“A” in FIG. 2) of the upper portion of the penetrating electrode 6 being larger than the thickness (“B” in FIG. 2) of the side portion of the penetrating electrode 6, the connection strength between the connection electrode 4 and the penetrating electrode 6 on the first surface 2a of the substrate 2 is increased, whereby it is possible to suppress the peeling of the connection electrode 4 off the first surface 2a of the substrate 2 in the upward direction in FIG. 1.

Consider a case where a stress urging the connection electrode 4 to peel off the first surface 2a of the substrate 2 acts upon the first surface 2a of the substrate 2. If the thickness (“A” in FIG. 2) of the upper portion of the penetrating electrode is smaller than the thickness (“B” in FIG. 2) of the side portion of the penetrating electrode unlike in the present embodiment, the connection electrode 4 may be disconnected or peeled off, by being ripped off, together with the upper portion of the penetrating electrode, by the stress urging the connection electrode 4 to peel off. If the thickness (“A” in FIG. 2) of the upper portion of the penetrating electrode 6 is larger than the thickness (“B” in FIG. 2) of the side portion of the penetrating electrode 6 as in the present embodiment, the connection electrode 4 is unlikely to be ripped off, together with the upper portion of the penetrating electrode 6, whereby it is possible to suppress the peeling of the connection electrode 4 off the first surface 2a of the substrate 2.

Moreover, in the present embodiment, the penetrating electrode 6 includes the depression 6a in a position opposing the reverse surface of the connection electrode 4, and the thickness (“A” in FIG. 2) of the upper portion of the penetrating electrode 6 is larger than the thickness (“B” in FIG. 2) of the side portion of the penetrating electrode 6, with a portion of the insulating layer 8 being inserted into the depression 6a of the penetrating electrode 6 from the side of the second surface 2b of the substrate 2. Also with this, it is possible to suppress the peeling of the connection electrode 4 off the first surface 2a of the substrate 2.

Specifically, a contractile force acts upon the insulating layer 8 when the portion of the insulating layer 8 that is inserted into the depression 6a of the penetrating electrode 6 cures. If the thickness (“A” in FIG. 2) of the upper portion of the penetrating electrode is smaller than the thickness (“B” in FIG. 2) of the side portion of the penetrating electrode unlike in the present embodiment, the contractile force of the inserted portion of the insulating layer 8 reaches the connection electrode 4 via an upper portion of the penetrating electrode 6, whereby the connection electrode 4 may be broken or peeled, together with the upper portion of the penetrating electrode 6, off the first surface 2a of the substrate 2 in the (downward) direction toward the second surface 2b of the substrate 2. In contrast, since the thickness (“A” in FIG. 2) of the upper portion of the penetrating electrode 6 is larger than the thickness (“B” in FIG. 2) of the side portion of the penetrating electrode 6 as described above in the present embodiment, the contractile force acting upon the insulating layer 8 is unlikely to reach the connection electrode 4 via the upper portion of the penetrating electrode 6. As a result, it is possible to suppress disconnection or peeling of the connection electrode 4 together with the upper portion of the penetrating electrode 6.

It is preferred that the thickness (“A” in FIG. 2) of the upper portion of the penetrating electrode 6 is 1/10 or more of the thickness of the substrate 2. While the thickness of the wiring electrode 7 is typically about 2/tm to about 15,um, it is preferred that the thickness (“A” in FIG. 2) of the upper portion of the penetrating electrode 6 is larger than the thickness of the wiring electrode 7. It is also preferred that the thickness (“A” in FIG. 2) of the upper portion of the penetrating electrode 6 is larger than the thickness of the connection electrode 4. Then, it is possible to improve, at the same time, the property of preventing the peeling of the insulating layer 8, the property of preventing the disconnection of the connection electrode 4, and the property of preventing the peeling of the connection electrode 4.

Where the substrate 2 is a silicon substrate, it is preferred that a thin silicon oxide film (thin SiO₂ film) 13 is formed across the first penetrating hole portion 5 and the second surface 2b of the substrate 2 by a CVD (Chemical Vapor Deposition) method, or the like, so as to ensure the insulation between the substrate 2 and the penetrating electrode 6 and the wiring electrode 7. Moreover, it is preferred that a thin titanium-based metal film or a thin chromium film (not shown as it is very thin) is formed on the thin silicon oxide film 13 by sputtering, or the like, and a thin copper film (not shown as it is very thin) is then formed on the thin titanium-based metal film or the thin chromium film by sputtering, or the like. In such a case, the penetrating electrode 6 and the wiring electrode 7 of a metal whose main component is copper are formed on the surface of the thin copper film. Note however that the thin silicon oxide film 13 is absent (removed in advance) at the connecting surface between the connection electrode 4 and the penetrating electrode 6, thereby ensuring an electrical connection between the connection electrode 4 and the penetrating electrode 6.

It is also preferred that the first penetrating hole portion 5 has such a cross section that the diameter on the first surface 2a of the substrate 2 is smaller than that on the second surface 2b of the substrate 2. Moreover, if the cross section of the first penetrating hole portion 5 is tapered so that the diameter of the first penetrating hole portion 5 on the first surface 2a of the substrate 2 is smaller than that on the second surface 2b of the substrate 2, the film formation conditions and the film thicknesses in the first penetrating hole portion 5 can be stabilized in the formation of the thin silicon oxide film 13 by a CVD method, or the like, as described above, the subsequent formation of the thin titanium-based metal film or the thin chromium film (not shown) by sputtering, or the like, and the subsequent formation of the thin copper film and the formation of the penetrating electrode 6. Thus, it is possible to stabilize the relationship between the thickness (“A” in FIG. 2) of the upper portion of the penetrating electrode 6 and the thickness (“B” in FIG. 2) of the side portion of the penetrating electrode 6, and the relationship between the thickness (“A” in FIG. 2) of the upper portion of the penetrating electrode 6 and the thickness of the wiring electrode 7.

While the electronic component 3 has a flush surface with the adhesive 11 lying entirely across the surface in FIG. 1, the electronic component 3 may have a cavity structure including a hollow portion (air layer) on the surface thereof.

Next, a method for manufacturing a substrate module according to an embodiment of the present invention will now be described.

First, the electronic component 3 is provided on the first surface 2a, and a plurality of connection electrodes 4, 4, . . . , are provided at predetermined intervals therebetween on the first surface 2a of the substrate 2 around the electronic component 3 (step (a)).

Then, the penetrating electrode 6 is formed. It is preferred that the penetrating electrode 6 is formed as follows by a plating process.

First, the first penetrating hole portion 5 is formed by, for example, dry etching, wet etching, or the like, from a portion of the second surface 2b of the substrate 2 that opposes the reverse surface of the connection electrode 4 (step (b)). In this step, it is preferred that the first penetrating hole portion 5 is formed so that the diameter thereof on the first surface 2a of the substrate 2 is smaller than that on the second surface 2b of the substrate 2.

Next, a CVD method, or the like, is performed from the side of the second surface 2b of the substrate 2 to thereby form the thin silicon oxide film 13 on the reverse surface of the connection electrode 4, the side surface of the first penetrating hole portion 5 and the second surface 2b of the substrate 2, after which a portion of the thin silicon oxide film 13 formed on the reverse surface of the connection electrode 4 is removed by dry etching, or the like. If the thin silicon oxide film 13 is present on the reverse surface of the connection electrode 4, it will be an insulator preventing the electrical connection between the penetrating electrode 6 and the connection electrode 4. Therefore, a portion of the thin silicon oxide film 13 that is present on the reverse surface of the connection electrode 4 is removed.

Then, a thin titanium-based metal film or a thin chromium film (not shown as it is very thin) and a thin copper film (not shown as it is very thin) are formed in this order by sputtering, or the like, on the surface of the thin silicon oxide film 13 formed on the side surface of the first penetrating hole portion 5 and the surface of the thin silicon oxide film 13 formed on the second surface 2b of the substrate 2, after which the penetrating electrode 6 and the wiring electrode 7 are formed by electrolytic plating using copper (steps (c) and (d)). In this step, the penetrating electrode 6 and the wiring electrode 7 may be formed simultaneously. Thus, the depression 6a can be formed in a portion of the penetrating electrode 6 that is opposing the reverse surface of the connection electrode 4, with the thickness (“A” in FIG. 2) of the upper portion of the penetrating electrode 6 being larger than the thickness (“B” in FIG. 2) of the side portion of the penetrating electrode 6.

It is preferred that the plating solution used in this process contains, as main components, a promoter (primarily PEG: polyethylene glycol) for promoting the deposition growth in the first penetrating hole portion 5 (primarily on the reverse surface of the connection electrode 4) and an inhibitor (primarily SPS: Bis(3-sulfopropyl)disulfid or JGB: Janus green B) for inhibiting the deposition growth on the second surface 2b of the substrate 2. Then, it is possible to increase the deposition thickness in the upper portion of the first penetrating hole portion 5 (primarily on the reverse surface of the connection electrode 4) while suppressing the deposition thickness on the second surface 2b of the substrate 2 and on the side portion of the first penetrating hole portion 5. The deposition thickness in the upper portion of the first penetrating hole portion 5 (primarily on the reverse surface of the connection electrode 4) can also be increased by appropriately changing plating conditions such as the current density or the stirring of the plating solution. Although part of the reason why the deposition thickness is increased by changing the plating conditions has not been elucidated, it is believed that a factor is how easily copper ions can stay on the surface.

Back to the method for manufacturing a substrate module, a thermosetting resin or a UV curable resin is applied with the substrate 2 including the penetrating electrode 6 formed therein being placed so that the second surface 2b is facing up. Then, the thermosetting resin or the UV curable resin is provided on the second surface 2b of the substrate 2 (more accurately, on the surface of the thin copper film) and also in the depression 6a of the penetrating electrode 6. Then, the second penetrating hole 9 is formed so as to reach the wiring electrode 7 by photolithography (step (f)). Then, the thermosetting resin or the UV curable resin is cured by heating or UV irradiation to thereby form the insulating layer 8 (step (e)).

Then, the mounting electrode 10 is provided in the second penetrating hole 9, and the mounting electrode 10 and the penetrating electrode 6 are connected to each other (step (g)). It is preferred that a solder material is primarily used for the mounting electrode 10. The mounting electrode 10 may be formed, for example, by applying a solder paste in the second penetrating hole 9 and then melting and curing the solder paste by a reflowing operation, or by applying a surfactant such as a flux in the second penetrating hole 9, placing a solder ball on the surfactant and then melting and curing the solder by a reflowing operation.

Thus, the mounting electrode 10 and the electronic component 3 are electrically connected to each other via the wiring electrode 7, the penetrating electrode 6 and the connection electrode 4.

Then, the substrate module 1 obtained as described above is provided in an electronic device such as a mobile telephone or a digital still camera by electrically connecting the mounting electrode 10 of the substrate module 1 to the surface of the wiring substrate of the electronic device.

While the above description of the present invention has been directed to an image-sensing device as an example of the electronic component 3, the present invention is also applicable to various other types of modules, such as an optical device, a photodiode, and a laser module.

What is claimed is:

1. A substrate module, comprising:
a substrate;
an electronic component provided on a first surface of the substrate or inside the substrate;
a connection electrode provided on the first surface of the substrate while being connected to the electronic component;
a first penetrating hole portion running through the substrate in a thickness direction thereof so as to reach a reverse surface of the connection electrode;
a penetrating electrode provided inside the first penetrating hole portion so as to extend from inside the first penetrating hole portion to a second surface of the substrate; and
a wiring electrode provided on the second surface of the substrate and connected to the penetrating electrode on the second surface of the substrate,
wherein inside the first penetrating hole portion, the penetrating electrode defines a depression in a position opposing the reverse surface of the connection electrode, and a thickness of the penetrating electrode on the reverse surface of the connection electrode is greater than that on a side surface of the first penetrating hole portion.

2. The substrate module of claim 1, wherein the thickness of the penetrating electrode on the reverse surface of the connection electrode is greater than a thickness of the wiring electrode.

3. The substrate module of claim 1, wherein the thickness of the penetrating electrode on the reverse surface of the connection electrode is greater than a thickness of the connection electrode.

4. The substrate module of claim 1, further comprising an insulating layer provided on the second surface of the substrate so as to cover a surface of the wiring electrode,
wherein the insulating layer is present also in the depression of the penetrating electrode.

5. The substrate module of claim 4, wherein:
a second penetrating hole is formed in the insulating layer;
a mounting electrode is provided in the second penetrating hole; and
the mounting electrode is connected to the wiring electrode.

6. The substrate module of claim 1, wherein the penetrating electrode is made of copper or a metal whose main component is copper.

7. The substrate module of claim 1, wherein:
the substrate is made of silicon;
a thin silicon oxide film, a thin titanium-based metal film or a thin chromium film, and a thin copper film are formed in this order on the side surface of the first penetrating hole portion; and
the penetrating electrode is made of a metal whose main component is copper and is provided on a surface of the thin copper film.

8. The substrate module of claim 7, wherein the thin silicon oxide film is absent between the penetrating electrode and the connection electrode.

9. The substrate module of claim 1, wherein a diameter of the first penetrating hole portion on the first surface of the substrate is smaller than that on the second surface of the substrate.

10. The substrate module of claim 9, wherein the first penetrating hole portion is tapered.

11. The substrate module of claim 4, wherein the insulating layer is made of a thermosetting resin.

12. The substrate module of claim 4, wherein the insulating layer is made of a UV curable resin.

13. A method for manufacturing a substrate module including an electronic component, the method comprising:
a step (a) of providing a connection electrode connected to the electronic component on a first surface of a substrate;
a step (b) of forming a first penetrating hole portion running through the substrate in a thickness direction thereof so as to reach a reverse surface of the connection electrode;
a step (c) of providing a penetrating electrode inside the first penetrating hole portion so that the penetrating electrode extends from inside the first penetrating hole portion to a second surface of the substrate; and
a step (d) of providing a wiring electrode on the second surface of the substrate, and connecting together the wiring electrode and the penetrating electrode on the second surface of the substrate,
wherein in the step (c), the penetrating electrode is provided so that a thickness of the penetrating electrode on the reverse surface of the connection electrode is greater than that on a side surface of the first penetrating hole portion, with the penetrating electrode defining a depression in a position opposing the reverse surface of the connection electrode.

14. The method for manufacturing a substrate module of claim 13, further comprising a step (e) of providing an insulating layer on the second surface of the substrate so as to cover a surface of the wiring electrode,
wherein in the step (e), the insulating layer is inserted into the depression of the penetrating electrode.

15. The method for manufacturing a substrate module of claim 14, further comprising:
a step (f) of forming a second penetrating hole in the insulating layer; and
a step (g) of providing a mounting electrode inside the second penetrating hole, and connecting together the mounting electrode and the wiring electrode.

16. The method for manufacturing a substrate module of claim 13, wherein the step (c) and the step (d) are performed simultaneously.

17. An electronic device, comprising:
the substrate module of claim 5; and
a wiring substrate,
wherein the mounting electrode of the substrate module is provided on a surface of the wiring substrate and is connected to the wiring substrate.
